(19) United States
(12) Patent Application Publication
(10) Pub. No.: US 2008/0124846 A1
(43) Pub. Date: May 29, 2008

(54) METHOD OF FABRICATING THIN FILM TRANSISTOR

(75) Inventors: Hao-Chieh Lee, Taoyuan (TW); Ching-Yun Chu, Taoyuan (TW)

Correspondence Address: J C PATENTS, INC., 4 VENTURE, SUITE 250, IRVINE, CA, 92618, US

(73) Assignee: QUANTA DISPLAY INC., Taoyuan (TW)

(21) Appl. No.: 11/536,444

(22) Filed: Sep. 28, 2006

(30) Foreign Application Priority Data
Jul. 14, 2006 (TW) 95125802

(51) Int. Cl. H01L 21/02

(52) U.S. Cl. 438/151; 257/E21.411

(57) ABSTRACT

A method of fabricating a thin film transistor is provided. A gate is formed on a substrate. Then, an insulating layer is formed on the substrate to cover the gate. A semiconductor layer is formed on the insulating layer above the gate. A source/drain is formed on the semiconductor layer. After forming the source/drain, a surface treatment process is performed.

### CROSS-REFERENCE TO RELATED APPLICATION

This application claims the priority benefit of Taiwan application serial no. 95125802, filed on Jul. 14, 2006. All disclosure of the Taiwan application is incorporated herein by reference.

### BACKGROUND OF THE INVENTION

1. Field of the Invention

The present invention relates to a method of fabricating a semiconductor device, and more particularly, to a method of fabricating a thin film transistor.

2. Description of Related Art

The rapid development of multi-media in our society is mostly the result of a series of breakthroughs in the fabrication of semiconductor devices and display devices. In the past, cathode ray tubes (CRT) have been the dominant displays in the market due to their high display quality and low cost.

However, in an environment where a number of terminals/displays is put on a desk for personal use, or where the concept of protecting the environment and the saving energy is most important, the poor spatial utilization and high power consumption of the CRT often cause many problems. Furthermore, there is no effective ways of reducing the bulk and energy consumption of the CRT. Therefore, thin film transistor liquid crystal displays (TFT LCD), with the advantages of high display quality, good spatial utilization, low power consumption and radiation-free operation, have gradually become one of the mainstream display products on the market.

The conventional method of fabricating a thin film transistor includes forming a gate on a substrate. Next, an insulating layer and a semiconductor layer are sequentially formed on the substrate to cover the gate. After that, a source/drain is formed on each side of the semiconductor layer to complete the fabrication of the thin film transistor.

Because the insulating layer and the semiconductor layer in the conventional method of fabricating the thin film transistor are formed in a chemical vapor deposition process and no additional process is used to strengthen the structure of the insulating layer and the semiconductor layer thereafter, the electrical performance of the thin film transistor is poor in addition to the current leakage problem. The current leakage problem can lead to a non-uniform display of pictures on the liquid crystal display panel such as a localized grayish-white tint within a black picture. Hence, the quality of the liquid crystal display is affected.

Furthermore, because the insulating layer and the semiconductor layer is structurally weak, the endurance of the thin film transistor is poor and the life span of the thin film transistor is short.

### SUMMARY OF THE INVENTION

Accordingly, at least one objective of the present invention is to provide a method of fabricating a thin film transistor capable of reinforcing the structure of an insulating layer and a semiconductor layer within the thin film transistor.

At least another objective of the present invention is to provide a method of fabricating a thin film transistor such that the thin film transistor has high endurance.

To achieve these and other advantages and in accordance with the purpose of the invention, as embodied and broadly described herein, the invention provides a method of fabricating a thin film transistor. First, a gate is formed on a substrate. Then, an insulating layer is formed on the substrate to cover the gate. After that, a semiconductor layer is formed on the insulating layer above the gate. Next, a source/drain is formed on the semiconductor layer. After forming the source/drain, a surface treatment process is performed.

In one preferred embodiment of the present invention, the surface treatment process in the foregoing method of fabricating the thin film transistor includes a gas annealing process.

In one preferred embodiment of the present invention, the gas annealing process in the foregoing method of fabricating the thin film transistor includes performing a gas annealing treatment once or twice.

In one preferred embodiment of the present invention, the gas used in the gas annealing process in the foregoing method of fabricating the thin film transistor is selected from the group consisting of nitrogen, hydrogen, ammonia, nitric oxide, nitrous oxide, nitrogen dioxide and oxygen.

In one preferred embodiment of the present invention, the gas annealing process in the foregoing method of fabricating the thin film transistor is performed at a temperature between about 200° C. to 450° C.

In one preferred embodiment of the present invention, the gas annealing process in the foregoing method of fabricating the thin film transistor is performed for a duration of about 5 seconds to one hour.

In one preferred embodiment of the present invention, the gas annealing process in the foregoing method of fabricating the thin film transistor is performed at a temperature between about 400° C. to 600° C.

In one preferred embodiment of the present invention, the gas annealing process in the foregoing method of fabricating the thin film transistor is performed for a duration of about 5 seconds to 30 minutes.

In one preferred embodiment of the present invention, a material of the semiconductor layer in the foregoing method of fabricating the thin film transistor includes amorphous silicon or low-temperature polysilicon.

In one preferred embodiment of the present invention, the step of forming the semiconductor layer in the foregoing method of fabricating the thin film transistor further includes forming an ohmic contact layer on the semiconductor layer.

The present invention also provides an alternative method of fabricating a thin film transistor. First, a gate is formed on a substrate. Then, an insulating layer is formed on the substrate to cover the gate. After that, a semiconductor layer is formed on the insulating layer above the gate. Next, a source/drain is formed on the semiconductor layer. A passivation layer is formed on the substrate to cover the source/drain. After forming the passivation layer, a surface treatment process is performed.

Accordingly, the method of fabricating a thin film transistor in the present invention includes performing a surface treatment process after forming the source/drain or the passivation layer. Thus, the structure of the insulating layer and the semiconductor layer are strengthened to prevent the appearance of current leakage and improve the display quality of the liquid crystal display.

Furthermore, the surface treatment process for fabricating the thin film transistor in the present invention increases the endurance of the thin film transistor so that the life span of the thin film transistor is extended.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention, where:

FIGS. 1A through 1D are schematic cross-sectional views illustrating the steps for fabricating a thin film transistor according to one embodiment of the present invention.

FIG. 2 is a schematic cross-sectional view illustrating the step for fabricating a thin film transistor according to another embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

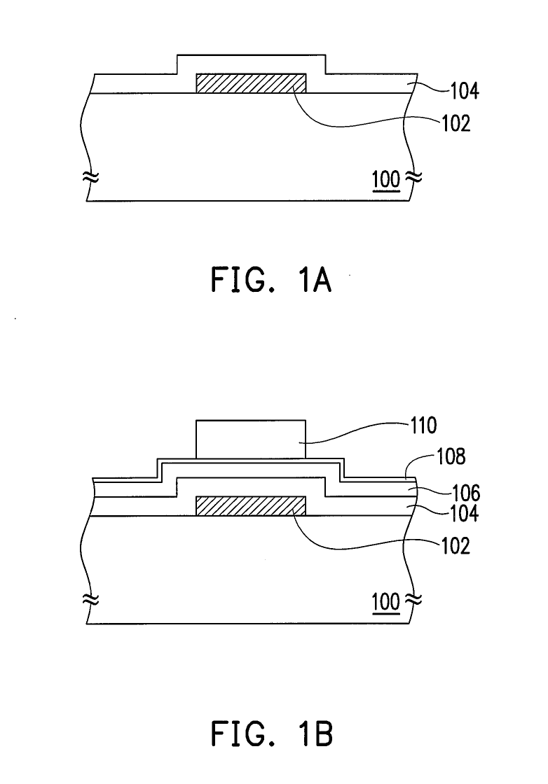

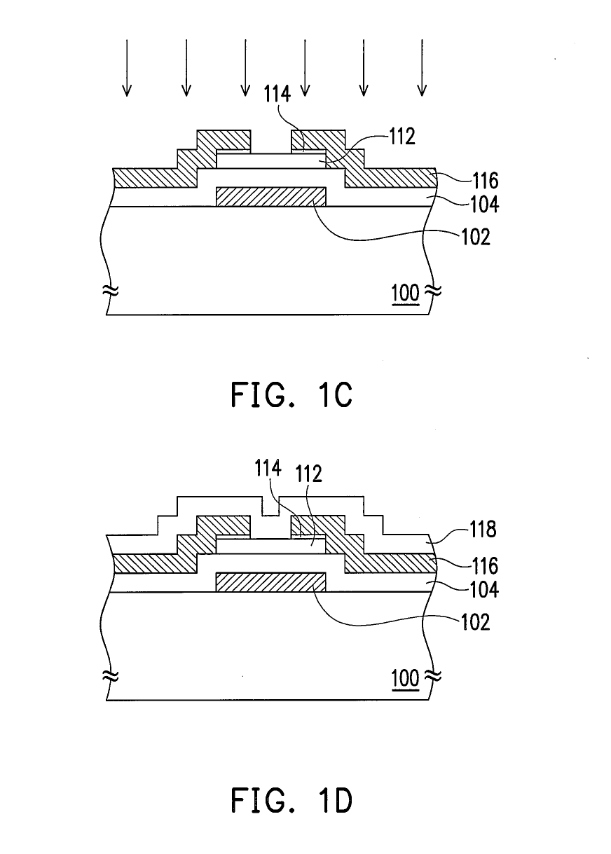

FIGS. 1A through 1D are schematic cross-sectional views illustrating the steps for fabricating a thin film transistor according to one embodiment of the present invention.

First, referring to FIG. 1A, a substrate 100 is provided. The substrate 100 can be a glass substrate or a quartz substrate.

Next, a gate 102 is formed on the substrate 100. The method of forming the gate 102 includes, for example, forming a first conductive layer (not shown) on the substrate 100 and patterning the first conductive layer. The first conductive layer may comprise a stack of metal layers. The first conductive layer is fabricated from a conductive material including, for example, aluminum, titanium, tin, tantalum, aluminum-silicon-copper, tungsten, chromium, copper, gold or silver. The method of forming the first conductive layer includes, for example, performing a physical vapor deposition process such as a sputtering process.

Next, an insulating layer 104 is formed on the substrate 100 to cover the gate 102. The insulating layer 104 is a dielectric material layer such as a silicon oxide layer or a silicon nitride layer formed by performing a chemical vapor deposition process, for example.

Next, referring to FIG. 1B, a semiconductor material layer 106 is formed on the insulating layer 104. The semiconductor material layer 106 is, for example, an amorphous silicon layer or a polysilicon layer. More specifically, the polysilicon is a low-temperature polysilicon layer. The method of forming the semiconductor material layer 106 includes performing a chemical vapor deposition process, for example.

In addition, an ohmic contact material layer 108 may also be formed on the semiconductor layer 106. The ohmic contact material layer 108 is a doped N+ amorphous silicon layer or N+ polysilicon layer and may be formed, for example, by performing a chemical vapor deposition process.

Thereafter, a patterned photoresist layer 110 is formed on the ohmic contact material layer 108 above the gate 102. The photo-exposure for patterning the photoresist layer 110 can be carried out using a photomask (not shown) as a mask. Alternatively, the gate 102 may serve as a mask in a back exposure process.

As shown in FIG. 1C, the semiconductor material layer 106 and the ohmic contact material layer 108 are patterned to form a semiconductor layer 112 and an ohmic contact layer 114. The method of patterning the semiconductor material layer 106 and the ohmic contact material layer 108 includes, for example, performing a dry etching process using the patterned photoresist layer 110 as a mask.

Next, a source/drain 116 is formed on the semiconductor layer 112. The source and the drain have no contact with each other. The method of forming the source/drain 116 includes, for example, forming a second conductive layer (not shown) on the substrate 100 over the insulating layer 104, the semiconductor layer 112 and the ohmic contact layer 114 and then patterning the second conductive layer. The second conductive layer may comprise a stack of metal layers. The second conductive layer can be fabricated using a conductive material including, for example, aluminum, titanium, tin, tantalum, aluminum-silicon-copper, tungsten, chromium, copper, gold or silver. The method of forming the second conductive layer includes performing a physical vapor deposition process such as a sputtering process. The method of patterning the second conductive layer includes, for example, performing a photolithographic process using a conventional mask or a half-tone mask to form a patterned photoresist layer (not shown) on the second conductive layer. Then, using the patterned photoresist layer as a mask, a dry etching process of the second conductive layer is performed. Finally, the patterned photoresist layer is removed to complete the patterning of the second conductive layer. It should be noted that a portion of the ohmic contact layer 114 is also removed in the process of patterning the second conductive layer.

After forming the source/drain 116, a surface treatment process is performed. The surface treatment process includes, for example, performing a gas annealing treatment process once or twice in order to repair the defects in the semiconductor layer 112 and lower the number of dangling bonds so that the insulating layer 104 is again structurally unimpaired. After reinforcing the insulating layer 104 and the semiconductor layer 112, the possibility of current leakage is reduced and the display quality of the liquid crystal display is improved. In addition, the surface treatment process is capable of increasing the endurance of the thin film transistor, thereby extending the life span of the thin film transistor. Furthermore, the surface treatment process can lower the threshold voltage of the thin film transistor and increases the conducting current.

The gas used in the gas annealing process is selected from the group consisting of nitrogen, hydrogen, ammonia, nitric oxide, nitrous oxide, nitrogen dioxide and oxygen. When the temperature of the gas annealing process is set between about 200° C. to 450° C., the gas annealing process is performed for a duration of about 5 seconds to one hour. Alternatively, if the temperature of the gas annealing process is set between about 400° C. to 600° C., the gas annealing process is performed for a duration of about 5 seconds to 30 minutes.

As shown in FIG. 1D, a passivation layer 118 may also be formed on the substrate 100 to cover the source/drain 116. The passivation layer 118 is a dielectric material layer including, for example, a silicon oxide layer or a silicon nitride layer. The passivation layer 118 is formed, for example, by performing a chemical vapor deposition process.

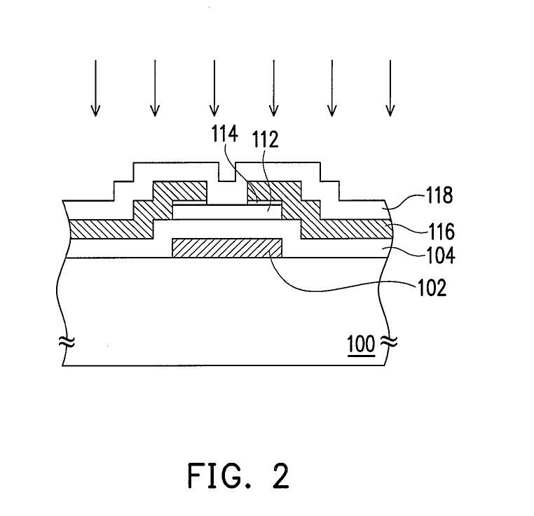

FIG. 2 is a schematic cross-sectional view illustrating the step for fabricating a thin film transistor according to another embodiment of the present invention. In this embodiment, aside from the surface treatment process, all other processes for fabricating the thin film transistor are identical to ones described in FIGS. 1A through 1D. Hence, detailed description thereof is not repeated.

As shown in FIG. 2, the surface treatment process is performed after forming the passivation layer 118 rather than after forming the source/drain 116. In the present embodiment, the surface treatment process includes, for example, performing a gas annealing process once or twice for repairing the defects in the semiconductor layer 112 and lowering the number of dangling bonds so that the insulating layer 104 and the semiconductor layer 112 is strengthened. Thus, the possibility of current leakage in the insulating layer and the semiconductor layer 112 may be effectively reduced and the display quality of the liquid crystal display may be improved. In addition, the surface treatment process can enhance the endurance of the thin film transistor so that the thin film transistor has a longer life span. Furthermore, the surface treatment process can also lower the threshold voltage of the thin film transistor and increase the conducting current. Since the processing parameter for performing the gas annealing process has been described in the previous embodiment, a detailed description is omitted here.

In summary, the present invention includes at least the following advantages:

1. The method of fabricating the thin film transistor in the present invention can reinforce the structure of the insulating layer and the semiconductor layer so that current leakage within the thin film transistor may be minimized and the display quality of the liquid crystal display may be improved.

2. The method of fabricating the thin film transistor according to the present invention has greater endurance.

3. The surface treatment process used for fabricating the thin film transistor lowers the threshold voltage of the thin film transistor and increases the conducting current.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating a thin film transistor, comprising:
forming a gate on a substrate;
forming an insulating layer on the substrate to cover the gate;
forming a semiconductor layer on the insulating layer above the gate;
forming a source/drain on the semiconductor layer; and
performing a surface treatment process after forming the source/drain.

2. The method of claim 1, wherein the surface treatment process comprises performing a gas annealing process.

3. The method of claim 2, wherein the gas annealing process comprises performing a gas annealing treatment once or twice.

4. The method of claim 2, wherein the gas used in the gas annealing process is selected from the group consisting of nitrogen, hydrogen, ammonia, nitric oxide, nitrous oxide, nitrogen dioxide and oxygen.

5. The method of claim 2, wherein a temperature for performing the gas annealing process is between about 200° C. to 450° C.

6. The method of claim 5, wherein the gas annealing process is performed for a duration of about 5 seconds to one hour.

7. The method of claim 2, wherein a temperature for performing the gas annealing process is between about 400° C. to 600° C.

8. The method of claim 7, wherein the gas annealing process is performed for a duration of about 5 seconds to 30 minutes.

9. The method of claim 1, wherein the semiconductor layer comprises amorphous silicon or low-temperature polysilicon.

10. The method of claim 1, wherein the step of forming the semiconductor layer further comprises forming an ohmic contact layer on the semiconductor layer.

11. A method of fabricating a thin film transistor, comprising:
forming a gate on a substrate;
forming an insulating layer on the substrate to cover the gate;
forming a semiconductor layer on the insulating layer above the gate;
forming a source/drain on the semiconductor layer;
forming a passivation layer on the substrate to cover the source/drain; and
performing a surface treatment process after forming the passivation layer.

12. The method of claim 11, wherein the surface treatment process comprises performing a gas annealing process.

13. The method of claim 12, wherein the gas annealing process comprises performing a gas annealing treatment once or twice.

14. The method of claim 12, wherein the gas used in the gas annealing process is selected from the group consisting of nitrogen, hydrogen, ammonia, nitric oxide, nitrous oxide, nitrogen dioxide and oxygen.

15. The method of claim 12, wherein a temperature for performing the gas annealing process is between about 200° C. to 450° C.

16. The method of claim 15, wherein the gas annealing process is performed for a duration of 5 seconds to one hour.

17. The method of claim 12, wherein a temperature for performing the gas annealing process is between about 400° C. to 600° C.

18. The method of claim 17, wherein the gas annealing process is performed for a duration of 5 seconds to 30 minutes.

19. The method of claim 11, wherein the semiconductor layer comprises amorphous silicon or low-temperature polysilicon.

20. The method of claim 11, wherein the step of forming the semiconductor layer further comprises forming an ohmic contact layer on the semiconductor layer.
